(19) United States
(12) Patent Application Publication
(10) Pub. No.: US 2026/0141856 A1
(43) Pub. Date: May 21, 2026

(54) ORGANIC LIGHT EMITTING ELEMENT

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); KUO-CHENG HSU, TAICHUNG CITY (TW); YICHANG WANG, ZHEJIANG PROVINCE (CN)

(21) Appl. No.: 19/370,823

(22) Filed: Oct. 28, 2025

Related U.S. Application Data
(60) Provisional application No. 63/722,081, filed on Nov. 19, 2024.

(30) Foreign Application Priority Data
Nov. 15, 2024 (CN) 202411640509.2
Aug. 29, 2025 (CN) 202511232710.1

(51) Int. Cl. G09G 3/3233; G09G 3/20; H10K 59/122; H10K 59/35

(52) U.S. Cl. CPC G09G 3/3233; G09G 3/2074; H10K 59/122; H10K 59/352; G09G 2300/0426; G09G 2320/0233

(57) ABSTRACT

An organic light-emitting element includes a substrate, and organic light-emitting units located over the substrate. Each of the organic light-emitting units includes a first electrode located over the substrate, an organic light-emitting layer located over the first electrode, and a second electrode located over the organic light-emitting layer. One of the first electrode and the second electrode includes a transparent conductive material, wherein at least two organic light-emitting units of the same color of light among the organic light-emitting units include organic light-emitting layers having different thicknesses.

### PRIORITY CLAIM AND CROSS-REFERENCE

This application claims the benefit of U.S. Provisional Application No. 63/722,081, filed on Nov. 19, 2024, and claims priority to China Patent Application Serial No. 202411640509.2, filed on Nov. 15, 2024, and China Patent Application Serial No. 202511232710.1, filed on Aug. 29, 2025, the entirety of which are incorporated by reference herein.

### BACKGROUND OF THE DISCLOSURE

### Field of the Disclosure

The present disclosure relates to an organic light-emitting element and a method for correcting pixel luminance values thereof, and more particularly to an organic light-emitting element including an organic light-emitting diode (OLED) structure and a method for correcting pixel luminance values thereof.

### Description of the Prior Art

Currently, a fine metal mask (FMM) is commonly used in a coating step for a light-emitting layer of an organic light-emitting element, or white light in combination with a color film are used for a manufacturing process. However, fineness or resolution of pixels resulted from the manufacturing process above is rather poor. Moreover, non-uniform luminances (also referred to as Mura defects) of pixels of an organic light-emitting element are one of the critical factors affecting the yield rate of the organic light-emitting element.

### SUMMARY OF THE DISCLOSURE

In the present disclosure, an organic light-emitting element includes a substrate, and a plurality of organic light-emitting units located over the substrate. Each of the organic light-emitting units includes a first electrode located over the substrate, an organic light-emitting layer located over the first electrode, and a second electrode located over the organic light-emitting layer. One of the first electrode and the second electrode includes a transparent conductive material, wherein at least two organic light-emitting units of the same color of light among the organic light-emitting units include organic light-emitting layers having different thicknesses.

In some embodiments, the first electrodes of the organic light-emitting element include a plurality of electrode portions arranged separately, the organic light-emitting layers include a plurality of first organic light-emitting layers, a plurality of second organic light-emitting layers and a plurality of third organic light-emitting layers configured to correspond to the electrode portions, respectively.

In some embodiments, a luminescence wavelength of the second organic light-emitting layers is greater than a luminescence wavelength of the first organic light-emitting layers, and at least two of the second organic light-emitting units of the organic light-emitting units include the second organic light-emitting layers having different thicknesses.

In some embodiments, at least two of the first organic light-emitting units of the organic light-emitting units include first organic light-emitting layers having different thicknesses.

In some embodiments, the luminescence wavelength of the first organic light-emitting layers is greater than a luminescence wavelength of the third organic light-emitting layers, and at least two of the third organic light-emitting units of the organic light-emitting units include third organic light-emitting layers having different thicknesses.

In some embodiments, the organic light-emitting element further includes pixel defined layers (PDL) to define a plurality of pixel regions, wherein the first electrodes include a plurality of electrode portions arranged separately in the pixel regions, the pixel defined layers include a plurality of protrusions partially covering the electrode portions, and at least two of the protrusions have different maximum vertical heights.

In some embodiments, the protrusions include an organic material.

In some embodiments, the protrusions in the pixel regions of at least two of the organic light-emitting units defined with the same color of light have different maximum vertical heights.

In some embodiments, under a same driving current, at least two organic light-emitting units emitting the same color of light among the organic light-emitting units have different luminances.

In some embodiments, under a same grayscale value, a portion of the organic light-emitting units emitting the same color of light among the organic light-emitting units has a same luminance, and the portion of the organic light-emitting units is arranged in a sloped line or an arc.

In some embodiments, the portion of the organic light-emitting units having the same luminance includes the organic light-emitting layers having the same thickness.

In some embodiments, the organic light-emitting element further includes a plurality of protrusions defining a plurality of pixel regions, at least two of the organic light-emitting layers of the same color of light are respectively a first light-emitting layer having a first thickness and a second light-emitting layer having a second thickness, and the protrusions include a first protrusion adjacent to the first light-emitting layer and a second protrusion adjacent to the second light-emitting layer, wherein the first thickness is less than the second thickness and a height of the first protrusion is greater than a height of the second protrusion.

In some embodiments, the organic light-emitting element has a first side edge and a second side edge, and the second side edge is opposite to the first side edge, wherein two of the organic light-emitting units including the organic light-emitting layers of the same color of light but different thicknesses are located in a horizontal direction and are respectively adjacent to the first side edge and the second side edge.

In some embodiments, at least three of the organic light-emitting units of the same color of light include organic light-emitting layers having different thicknesses.

In some embodiments, the organic light-emitting element includes a plurality of pixel regions arranged in matrices along a first direction and a second direction, and each of the pixel regions includes at least three of the organic light-emitting units of different colors of light, wherein the organic light-emitting units of at least two of the pixel regions arranged along the first direction or the second direction include organic light-emitting layers having different thicknesses.

In some embodiments, a method for correcting pixel luminance values of an organic light-emitting element includes: providing the organic light-emitting element described above, wherein the organic light-emitting element includes a plurality of pixels and a pixel driving circuit, and the pixel driving circuit includes a driving transistor configured to provide driving currents to the respective pixels; applying the driving currents to the respective pixels by the driving transistor; obtaining a grayscale image to be processed of the pixels; calculating a balance luminance value of the grayscale image to be processed; determining a luminance difference between a luminance value of each of the pixels and the balance luminance value; and adjusting the driving currents to the respective pixels to compensate for the luminance difference.

In some embodiments, in the method for correcting pixel luminance values of an organic light-emitting element above, the pixels of a set color of the organic light-emitting element are lit by a set grayscale value to obtain the grayscale image to be processed, and the grayscale image to be processed has a non-uniform optical shadow pattern.

In some embodiments, in the method for correcting pixel luminance values of an organic light-emitting element above, the grayscale image to be processed of the pixels is obtained by an image capturing device, the image capturing device includes a memory, a processor and a computer program stored in the memory and operable on the processor, and the processor executes the computer program to implement steps of the method for correcting pixel luminance values of the grayscale image to be processed.

In some embodiments, in the method for correcting pixel luminance values of an organic light-emitting element above, the grayscale image to be processed of the pixels is obtained by an image capturing device, the image capturing device is coupled to a computer readable storage medium, and luminance values of the grayscale image to be processed thus captured and obtained are calculated by a computer program stored in the computer readable storage medium to obtain updated driving current values for the respective pixels.

In some embodiments, a greater driving current is provided to pixels having lower luminances, and a smaller driving current is provided to pixels having greater luminances.

### BRIEF DESCRIPTION OF THE DRAWINGS

FIG. 1A is a cross-sectional diagram of an intermediate structure of a manufacturing method of an organic light-emitting element according to some embodiments;

FIG. 1B is a top view of an intermediate structure of a manufacturing method of an organic light-emitting element according to some embodiments;

FIG. 2A is a cross-sectional diagram of an intermediate structure of a manufacturing method of an organic light-emitting element according to some embodiments;

FIG. 2B is a cross-sectional diagram of an intermediate structure of a manufacturing method for an organic light-emitting element according to some embodiments;

FIG. 2C is a cross-sectional diagram of an intermediate structure of an organic light-emitting element from which the patterned photoresist layer in FIG. 2B is removed;

FIG. 3A is a top view of a substrate of an intermediate product of an organic light-emitting element according to some embodiments;

FIG. 3B is a partial top view of one of the regions in FIG. 3A, and shows an intermediate product of a part of an organic light-emitting element;

FIG. 4 is a micrograph of a partial area of an organic light-emitting element according to some embodiments;

FIG. 5 is a flowchart of a method for correcting a pixel luminance value of an organic light-emitting element according to some embodiments of the present disclosure;

FIG. 6 is a cross-sectional diagram taken along the line 1A-1A′ in FIG. 3B;

FIG. 7A to FIG. 7F depict a manufacturing method of an organic light-emitting element in FIG. 6 according to some embodiments; and

FIG. 8 is a schematic diagram of organic light-emitting layers of different organic light-emitting units of an organic light-emitting element according to some embodiments.

### DETAILED DESCRIPTION OF THE EMBODIMENTS

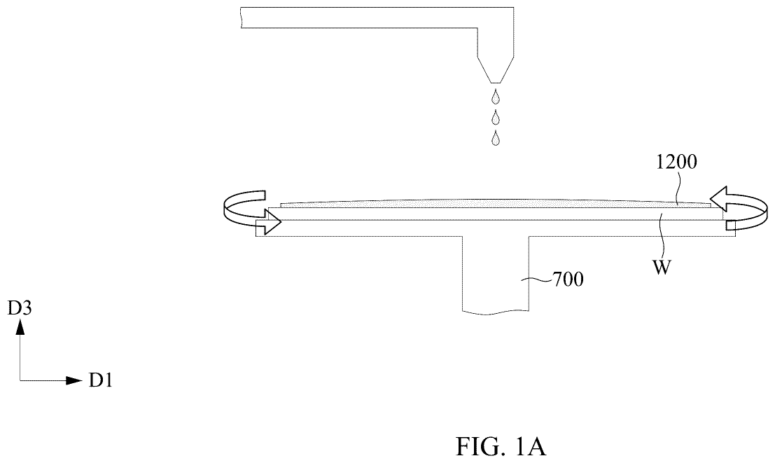

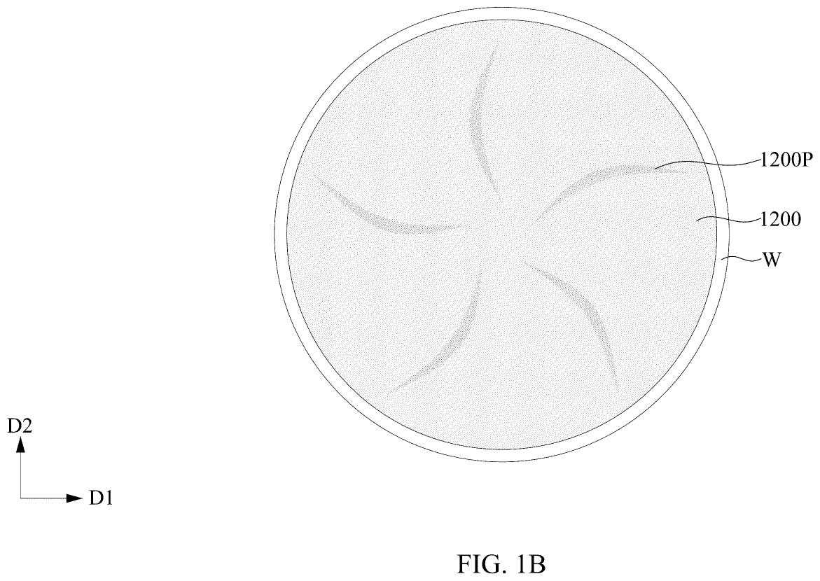

FIG. 1A shows a cross-sectional diagram of an intermediate structure of a manufacturing method of an organic light-emitting element according to some embodiments. In some embodiments, as shown in FIG. 1A, when a step of patterning a substrate such as a wafer W is performed, a photoresist 1200 may be formed by means of spin coating. In some embodiments, the wafer W is arranged on a spin coater 700, then a liquid photoresist is applied onto the wafer W, and the liquid photoresist subject to the centrifugal force extends from a central region of the wafer W to a periphery by rotation of the spin coater 700.

FIG. 1B shows a top view of an intermediate structure of a manufacturing method of an organic light-emitting element according to some embodiments. In some embodiments, as shown in FIG. 1B, due to viscosity of the liquid photoresist, while the liquid photoresist is thrown by the centrifugal force and dispersed from the central region of the wafer W toward the periphery, it is possible that a non-uniform thickness may be caused in some regions after the liquid photoresist is dispersed. Thus, when viewing from an upper surface, one or more optical shadow arcs 1200P extending outward from the central region and thrown along the direction of rotation of the spin coater 700 may be observed. These optical shadow arcs 1200P are gloss of appearances or optical shadow patterns observed due to the non-uniform thickness of the photoresist 1200 that produces different reflections and/or refractions of light.

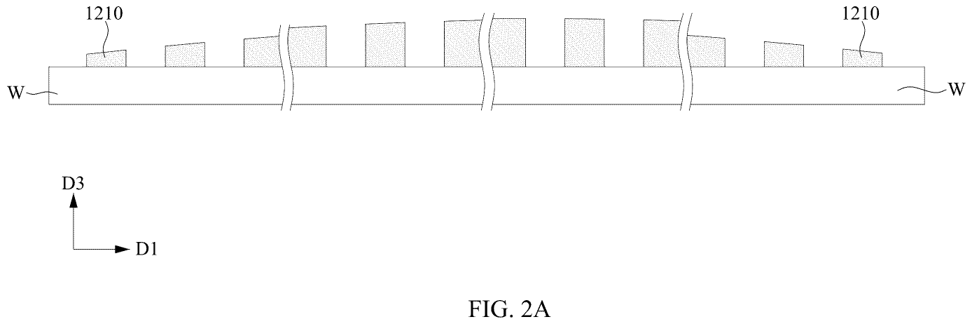

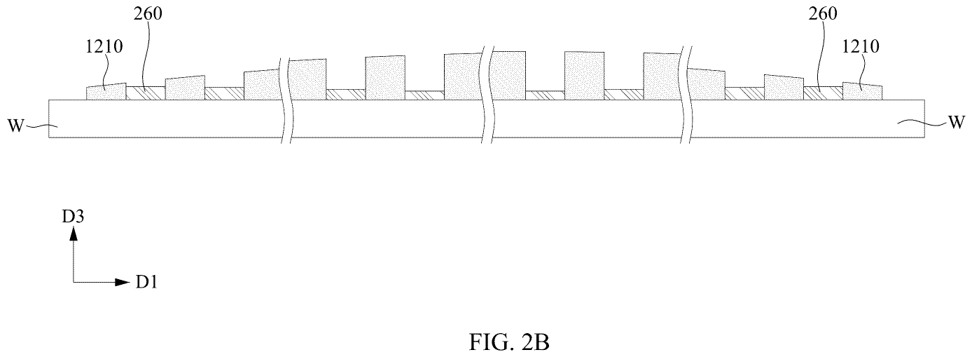

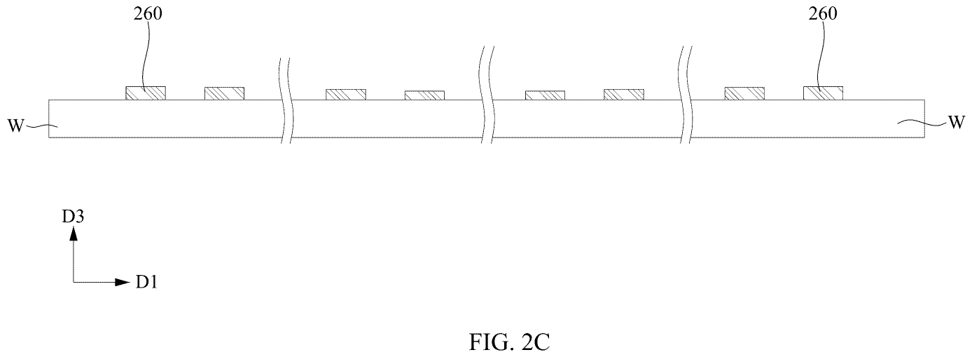

FIG. 2A shows a cross-sectional diagram of an intermediate structure of a manufacturing method of an organic light-emitting element according to some embodiments. In some embodiments, the thickness of the photoresist formed by means of spin coating may gradually decrease in a direction from the central region of the wafer W toward the outer periphery. Thus, after the patterning processes performed on the photoresist, the thickness of a patterned photoresist layer 1210 thus formed also gradually decreases in a direction from the central region of the wafer W toward the outer periphery, as shown in FIG. 2A.

FIG. 2B shows a cross-sectional diagram of an intermediate structure of a manufacturing method of an organic light-emitting element according to some embodiments. In some embodiments, as shown in FIG. 2B, an organic light-emitting layer 260 is formed by means of evaporation on an electrode (not shown in FIG. 2A to FIG. 2C) of an opening defined by the patterned photoresist layer 1210. In some embodiments, since the thickness of the photoresist for multiple openings defined by the patterned photoresist layer 1210 decreases gradually from the central region toward the outer periphery, the organic light-emitting layer 260 filled therein also contains differences in thickness.

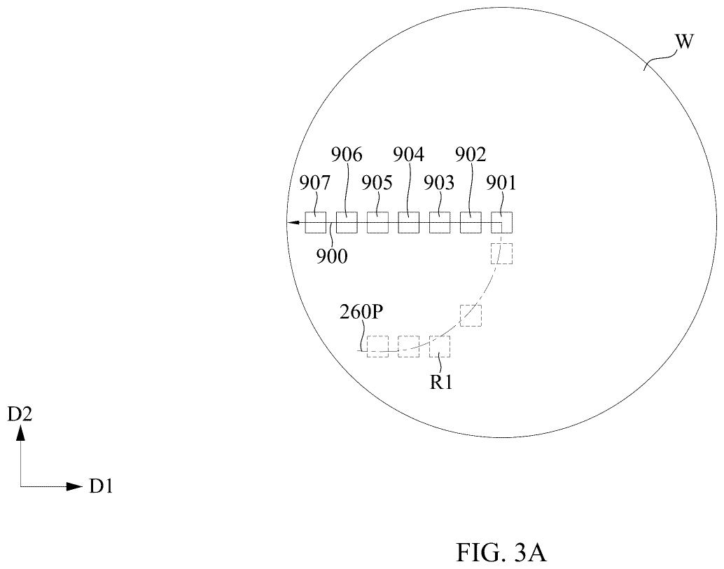

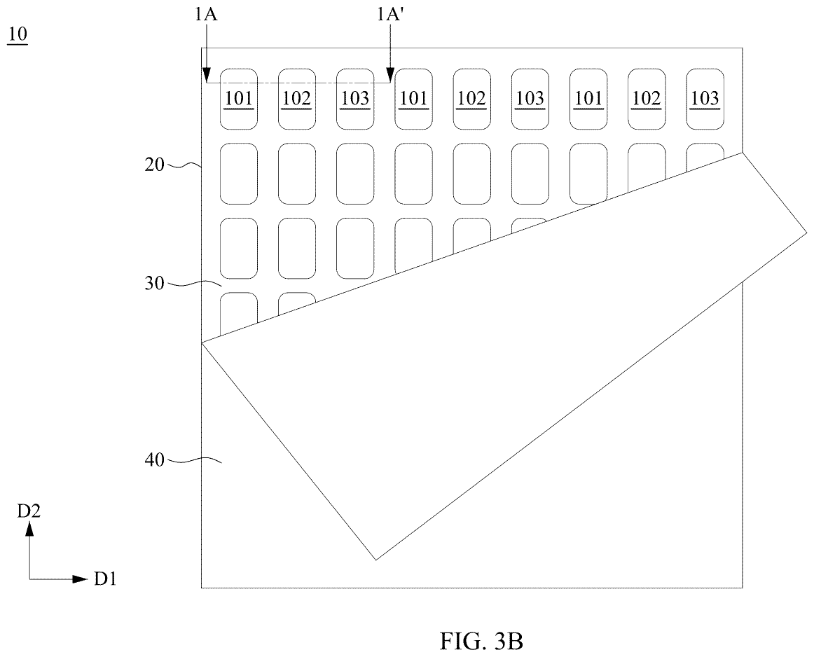

In some embodiments, when the aspect ratio of an opening of the patterned photoresist layer 1210 are smaller, for example, an opening closer to the outer periphery, it is easy for the organic light-emitting layer 260 to fill therein; when the aspect ratio of an opening of the patterned photoresist layer 1210 are larger, for example, an opening closer to the central region, it is more challenging for the organic light-emitting layer 260 to fill therein. Thus, for the portion of the patterned photoresist layer 1210 having a greater thickness, the opening thereof is deeper, and a film layer of the organic light-emitting layer 260 formed (for example, by means of evaporation) is thinner; for the portion of the patterned photoresist layer 1210 having a smaller thickness, the opening thereof is shallower, and a film layer of the organic light-emitting layer 260 formed (for example, by means of evaporation) is thicker. FIG. 2C shows a cross-sectional diagram of an intermediate structure of an organic light-emitting element from which the patterned photoresist layer 1210 in FIG. 2B is removed. Multiple sub-pixels formed by these organic light-emitting layers 260 having different thicknesses similarly generate gloss or optical shadow patterns due to different reflections and/or refractions of light, and visually produce optical shadow arcs (260P in FIG. 3A, similar to the optical shadow arcs 1200P produced by the photoresist above).

FIG. 3A shows a top view of a substrate of an intermediate product of an organic light-emitting element according to some embodiments. FIG. 3A shows a plurality of regions 901 to 907 arranged along a radius 900 of the wafer W. FIG. 3B shows a partial top view of one of the regions in FIG. 3A, and shows an intermediate product of a part of an organic light-emitting element. In some embodiments, an organic light-emitting element 10 includes a light-emitting layer 20 and a cover layer 40 located over the light-emitting layer 20. For the light-emitting layer 20, a spacer structure 30 may be designed to define a pixel region so as to define a light-emitting pixel array. Moreover, refer to FIG. 3B for portions of organic light-emitting elements of other regions in FIG. 3A.

In some embodiments, the spacer structure 30 includes pixel defined layers (PDL), for example, protrusions, to provide a recess array used to accommodate the light-emitting pixel array. In some embodiments, the spacer structure 30 may include a photosensitive material made into protrusions, and may serve as pixel defined layers.

In some embodiments, taking the organic light-emitting element shown in FIG. 3A for example, the regions 901 to 907 are arranged along the radius 900 of the wafer W. The thickness of the patterned photoresist layer used to define positions of organic light-emitting layers may gradually decrease from the center of the wafer W toward the outer periphery, so that the organic light-emitting layers filled below may have different thicknesses. Thus, in pixel regions of any two regions, for example, in a pixel region of the region 901 and a pixel region of the region 907, it is possible that at least two organic light-emitting units of the same color of light include organic light-emitting layers having different thicknesses.

In some embodiments, taking an organic light-emitting element in one of the regions 901 to 907 for example, as shown in FIG. 3B, the organic light-emitting element 10 includes multiple pixel regions arranged along a first direction D1 and a second direction D2, and each of the pixel regions includes at least three of organic light-emitting units 101, 102 and 103 of different colors of light. In some embodiments, the first direction D1 is perpendicular to the second direction D2. In some embodiments, the first direction D1 or the second direction D2 is parallel to an extension direction of the radius 900 of the wafer W. In some embodiments, as shown in FIG. 3B, at least two of the organic light-emitting units of the same color of light in different pixel regions include organic light-emitting layers having different thicknesses.

In some embodiments, as shown in FIG. 3B, it is possible that two organic light-emitting units 101 separated by the organic light-emitting units 102 and 103 in the first direction D1 include organic light-emitting layers having different thicknesses due to changes in the thickness of the patterned photoresist layer. It is possible that two organic light-emitting units 102 separated by the organic light-emitting units 103 and 101 in the first direction D1 include organic light-emitting layers having different thicknesses due to changes in the thickness of the patterned photoresist layer. For example, it is possible that two organic light-emitting units 103 separated by the organic light-emitting units 101 and 102 in the first direction D1 include organic light-emitting layers having different thicknesses due to changes in the thickness of the patterned photoresist layer.

Moreover, in some embodiments, the multiple sub-pixels formed by the organic light-emitting layers 260 having different thicknesses as described above generate gloss or optical shadow patterns due to different reflections and/or refractions of light, such that multiple optical shadow arcs 260P are visually produced. Patterns of these optical shadow arcs 260P produced due to the organic light-emitting layers 260 having different thicknesses are similar to the optical shadow arcs 1200P produced by the photoresist above (FIG. 1B). One of the optical shadow arcs 260P is shown in FIG. 3A as illustration. A range defined by this optical shadow arc 260P may also be referred to as a optical shadow pattern, and the thickness of the organic light-emitting layer below the optical shadow pattern is different from the thickness of the organic light-emitting layer of a region outside the optical shadow pattern.

Moreover, as the wafer W shown in FIG. 3A, after singulation and packaging, because only a partial area (for example, one quadrilateral unit area) of the wafer W is cut, only a range defined by a portion of the optical shadow arc 260P passes through this partial area and visually appears more like a sloped line.

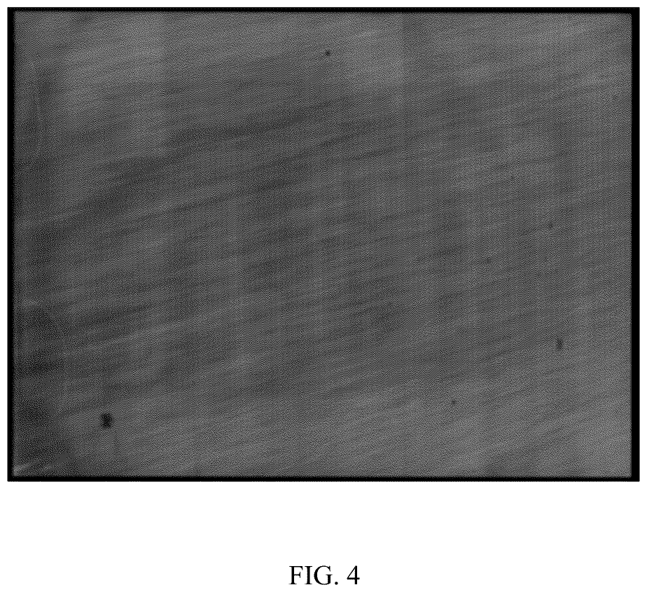

FIG. 4 shows a micrograph of a partial area of an organic light-emitting element according to some embodiments. In some embodiments, FIG. 4 shows a partial micrograph of a region R1 of an organic light-emitting element as shown in FIG. 3A, and multiple optical shadow sloped lines are presented. FIG. 4 shows a macro appearance of a surface of one organic light-emitting diode (OLED) wafer (or an organic light-emitting element) including multiple pixels. In some embodiments, the sub-pixels of a set color (for example, red) in a display panel are lit alone by a set grayscale value (for example, a grayscale value 128), while the grayscales of all of the sub-pixels of the remaining colors (for example, green and blue) are 0; that is, the grayscales of sub-pixels of all set colors in the display panel are the same set grayscale value (for example, a grayscale value 128). FIG. 4 is a micrograph when red sub-pixels are set to a grayscale value 128.

FIG. 4 shows multiple optical shadow patterns, which are formed by an organic light-emitting layer of multiple sub-pixels, and the non-uniformity of these optical shadows constitute a Mura region of the organic light-emitting element. In some embodiments, the optical shadow pattern has a pattern of arcs or sloped lines. In some embodiments, the optical shadow pattern has a neon glow similar to a rainbow.

Refer to both FIG. 3A and FIG. 4, in some embodiments, the shape and position of the optical shadow pattern of the organic light-emitting element, for example, the optical shadow arc 260P, correspond to the shape and position of the optical shadow arcs 1200P (from the photoresist 1200) in FIG. 1B. In some embodiments, each optical shadow pattern (having a range defined by the optical shadow arc 260P) of the organic light-emitting element may be formed by hundreds or thousands of pixels. In some embodiments, each optical shadow pattern may be formed by an organic light-emitting layer having a same color in hundreds or thousands of pixels. In some embodiments, the thickness of the organic light-emitting layer below the optical shadow pattern is different from the thickness of the organic light-emitting layer of a region outside the optical shadow pattern.

Moreover, in some embodiments, a region of the optical shadow pattern and a region outside the optical shadow pattern may be provided with different driving currents to compensate for Mura of the organic light-emitting element to achieve recovery of such Mura defect (DeMura). In some embodiments, gradually increased, gradually decreased or designed driving currents may be provided for luminance differences resulted from differences in the thickness of the organic light-emitting layer in the region of the optical shadow pattern to prevent display of Mura defects of the organic light-emitting element. In some embodiments, different driving currents may be provided based on distribution of the optical shadow patterns by driving circuits of the organic light-emitting element to eliminate Mura of the organic light-emitting element.

A method for correcting a pixel luminance value of an organic light-emitting element is described below. However, the present disclosure is not limited to applying this method, and other correction method able to achieve luminance balance to eliminate Mura may also be applied in conjunction with the organic light-emitting element of the embodiment.

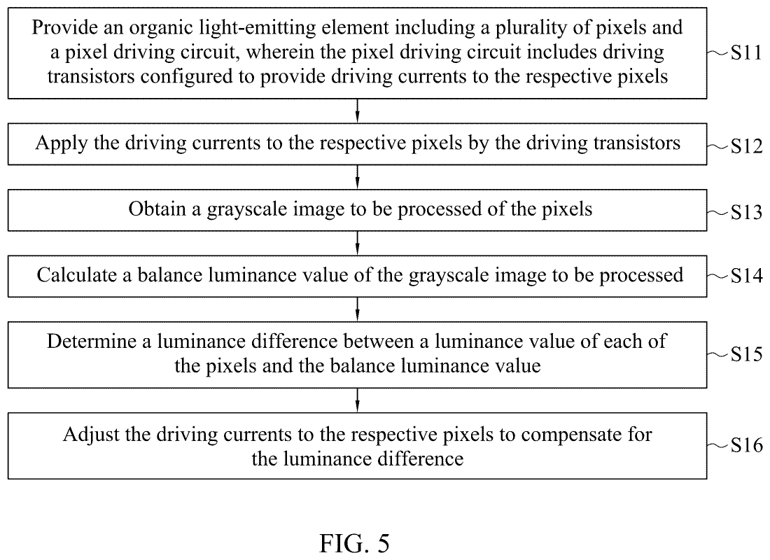

FIG. 5 shows a flowchart of a method for correcting a pixel luminance value of an organic light-emitting element according to some embodiments of the present disclosure. In step S11, an organic light-emitting element according to some embodiments is provided, wherein the organic light-emitting element includes a plurality of pixels and a pixel driving circuit, and the pixel driving circuit includes driving transistors configured to provide driving currents to the respective pixels. In step S12, driving currents are applied to the respective pixels of the organic light-emitting element by the driving transistors to display a grayscale image to be processed. Then, in step S13, the grayscale image to be processed of the pixels is obtained. In some embodiments, the grayscale image to be processed of the pixels of the organic light-emitting element may be obtained by an image capturing device (not shown). In step S14, a balance luminance value of the grayscale image to be processed is calculated. In step S15, a luminance difference between a luminance value of each of the pixels and the balance luminance value is determined. In step S16, the driving currents to the respective pixels are adjusted to compensate for the luminance difference.

In some embodiments, the grayscale image to be processed of the pixels is obtained by an image capturing device, and the image capturing device may include a memory, a processor and a computer program stored in the memory and operable on the processor. The steps of the method for correcting a pixel luminance value of the grayscale image to be processed are implemented when the processor executes the computer program.

In some embodiments, the image capturing device is coupled to a computer readable storage medium. After the grayscale image to be processed of the pixels is obtained by an image capturing device, luminance values of the grayscale image to be processed thus captured and obtained are calculated by the computer program stored in the computer readable storage medium to obtain an updated driving current value for each of the pixels.

In some embodiments, it is possible that the thickness of the organic light-emitting layer 260 (FIG. 2B and FIG. 2C) of a pixel having a lower luminance in the grayscale image to be processed is thinner, and the updated driving current value may be obtained according to calculation performed by the computer program. This updated driving current value is greater than the original driving current to increase the pixel luminance value, which then becomes approximate to or equal to the balance luminance value.

In some embodiments, it is possible that the thickness of the organic light-emitting layer 260 of a pixel having a higher luminance in the grayscale image to be processed is thicker, and the updated driving current value may be obtained according to calculation performed by the computer program. This updated driving current value is less than the original driving current to decrease the pixel luminance value, which then becomes approximate to or equal to the balance luminance value.

Thus, in the organic light-emitting element of the embodiment, Mura defects (as the bright sloped or arc marks in the micrograph in FIG. 4) are present before luminance compensation is performed. However, after the luminance compensation (such as having undergone the calculation and updated the driving current), the micrograph of partial regions of the organic light-emitting element becomes free of such bright marks. Therefore, after correction on the organic light-emitting element of the embodiment, the luminance difference between the pixels can be compensated to eliminate Mura (that is, DeMura), hence solving the issues of non-uniform display luminance and poor uniformity of a display image.

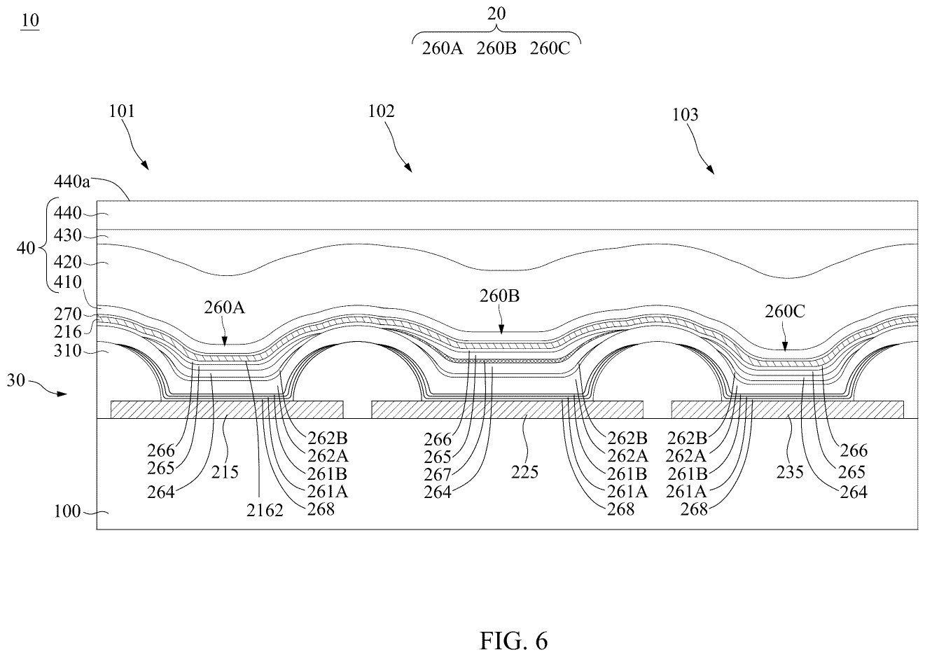

A partial cross-sectional diagram of an organic light-emitting element 10 according to some embodiments is described below. In some embodiments, FIG. 6 shows a cross-sectional diagram taken along the line 1A-1A′ in FIG. 3B, and only a light-emitting region is illustrated.

As shown in FIG. 3B and FIG. 6, in some embodiments, the spacer structure 30 includes a plurality of protrusions 310 to define a light-emitting pixel pattern. A recess is located between two adjacent protrusions 310 and provides a space for accommodating light-emitting pixels. In some embodiments, the protrusions 310 may include a photosensitive material. When viewing the cross-sectional diagram shown in FIG. 6, a person skilled in the art would be able to understand that the protrusions 310 are depicted in a disconnected manner. However, when viewing the schematic top view of FIG. 3B, the protrusions 310 can be connected to one another by other parts of the spacer structure 30.

As shown in FIG. 6, in some embodiments, the organic light-emitting element 10 is, for example, a light-emitting element including an organic light-emitting diode (OLED) structure. In some embodiments, the organic light-emitting element 10 includes a plurality of organic light-emitting units (or referred to as light-emitting pixels), for example, including at least an organic light-emitting unit 101 (or referred to as a first organic light-emitting unit), an organic light-emitting unit 102 (or referred to as a second organic light-emitting unit), and an organic light-emitting unit 103 (or referred to as a third organic light-emitting unit). In some embodiments, the organic light-emitting units 101, 102 and 103 are between the protrusions 310 and above a substrate 100. The organic light-emitting units 101, 102 and 103 may emit light having the same wavelength or light having different wavelengths.

In some embodiments, the organic light-emitting element 10 includes the substrate 100, an electrode 215, an electrode 225, an electrode 235, an electrode 216, a light-emitting layer 20, an inorganic barrier layer 268, an inorganic barrier layer 270, a spacer structure 30 and a cover layer 40.

In some embodiments, the substrate 100 may include a transistor array, which is configured to correspond to light-emitting pixels in the light-emitting layer 20. The substrate 100 may include a plurality of capacitors. In some embodiments, more than one transistor is configured with one capacitor and one light-emitting pixel to form a circuit. In some embodiments, the substrate 100 may include glass.

In some embodiments, the electrode 215, the electrode 225 and the electrode 235 are located over the substrate 100. In some embodiments, the electrodes 215, 225 and 235 are anodes. In some embodiments, the electrodes 215, 225 and 235 include a metal material, for example, Ag, Al, Mg, Au, AlCu alloy or AgMo alloy. In some embodiments, the electrodes 215, 225 and 235 include indium tin oxide (ITO), indium zinc oxide (IZO) or other appropriate materials.

In some embodiments, the light-emitting layer 20 includes an organic light-emitting layer 260A (or referred to as a first organic light-emitting layer), an organic light-emitting layer 260B (or referred to as a second organic light-emitting layer) and an organic light-emitting layer 260C (or referred to as a third organic light-emitting layer). In some embodiments, the organic light-emitting layer 260A is located over the electrode 215, the organic light-emitting layer 260B is located over the electrode 225, and the organic light-emitting layer 260C is located over the electrode 235. In some embodiments, the thickness of the organic light-emitting layer 260A, the thickness of the organic light-emitting layer 260B and the thickness of the organic light-emitting layer 260C are different from one another. In some embodiments, the thickness of the organic light-emitting layer 260B is greater than the thickness of the organic light-emitting layer 260A, and the thickness of the organic light-emitting layer 260A is greater than the thickness of the organic light-emitting layer 260C.

In some embodiments, the organic light-emitting layers 260A, 260B and 260C emit light having the same color or different colors. In some embodiments, the luminescence wavelength of the organic light-emitting layer 260B is greater than the luminescence wavelength of the organic light-emitting layer 260A, and the luminescence wavelength of the organic light-emitting layer 260A is greater than the luminescence wavelength of the organic light-emitting layer 260C. In some embodiments, the organic light-emitting layer 260A emits green light, the organic light-emitting layer 260B emits red light, and the organic light-emitting layer 260C emits blue light.

In some embodiments, the organic material layers of the organic light-emitting layers 260A, 260B and 260C include an organic material, which may be placed in any of the organic material layers of the organic light-emitting layers 260A, 260B and 260C according to different embodiments. In some embodiments, for a specific wavelength, the organic material has an absorption rate of greater than or equal to 50%, greater than or equal to 60%, greater than or equal to 70%, greater than or equal to 80%, greater than or equal to 90%, or greater than or equal to 95%. In some embodiments, the specific wavelength is not greater than 400 nm, not greater than 350 nm, not greater than 300 nm, not greater than 250 nm, not greater than 200 nm, not greater than 150 nm, or not greater than 100 nm.

As shown in FIG. 6, in some embodiments, the organic light-emitting unit 101 includes the electrode 215, the organic light-emitting layer 260A, and the electrode 216. In some embodiments, the organic light-emitting layer 260A includes multiple organic material layers, for example, a hole injection layer (HIL) 261A, a hole injection layer (HIL) 261B, a hole transport layer (HTL) 262A, a hole transport layer (HTL) 262B, an organic emissive layer (EML) 264, an electron transport layer (ETL) 265 and an electron injection layer (EIL) 266. In some embodiments, the electrode 216 is located above the organic light-emitting layer 260A.

As shown in FIG. 6, in some embodiments, the organic light-emitting unit 102 includes the electrode 225, the organic light-emitting layer 260B, and the electrode 216. In some embodiments, the organic light-emitting layer 260B includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, a hole blocking layer (HBL) 267, the electron transport layer (ETL) 265 and the electron injection layer (EIL) 266. In some embodiments, the electrode 216 is located above the organic light-emitting layer 260B.

As shown in FIG. 6, in some embodiments, the organic light-emitting unit 103 includes the electrode 235, the organic light-emitting layer 260C, and the electrode 216. In some embodiments, the organic light-emitting layer 260C includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, the electron transport layer (ETL) 265 and the electron injection layer (EIL) 266. In some embodiments, the electrode 216 is located above the organic light-emitting layer 260C. In some embodiments, the electrode 216 is a cathode.

In some embodiments, the electrode 216 is in contact with the organic light-emitting layers 260A, 260B and 260C. The electrode 216 may be a continuous film as shown in FIG. 6 and be located over the organic light-emitting layers 260A, 260B and 260C and the protrusions 310. In some embodiments, the electrode 216 may be further located over the spacer structure 30. In some embodiments, the electrode 216 is a common electrode of all light-emitting pixels in the light-emitting layer 20. In some embodiments, the electrode 216 includes a metal material, for example, Ag, Al, Mg, Au, AlCu alloy or AgMo alloy. In some embodiments, the electrode 216 includes ITO, IZO or other appropriate materials. In other words, the electrode 216 is a common electrode of a plurality of organic light-emitting units. In some embodiments, the electrode 216 is a common electrode of all organic light-emitting units in the organic light-emitting element 10.

In some embodiments, the spacer structure 30 is located over the substrate 100 and partially covers the electrodes 215, 225 and 235. In some embodiments, the spacer structure 30 is located among the organic light-emitting layers 260A, 260B and 260C. In some embodiments, the spacer structure 30 may include the protrusions 310. In some embodiments, the pattern of the spacer structure 30 is designed according to a pixel layout. In some embodiments, the spacer structure 30 serves as a pixel defined layer (PDL). In some embodiments, the protrusions 310 define a pixel region. In some embodiments, each protrusion 310 fills a gap between two adjacent ones of the electrodes 215, 225 and 235. Each of the electrodes 215, 225 and 235 is partially covered by the protrusion 310. In some embodiments, the spacer structure 30 includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a blackbody material, which has an absorption rate of greater than or equal to 90%, 95%, 99%, 99.5% or 99.9% for visible light.

In some embodiments, for a specific wavelength, the spacer structure 30 has an absorption rate of greater than or equal to 50%, greater than or equal to 60%, greater than or equal to 70%, greater than or equal to 80%, greater than or equal to 90%, or greater than or equal to 95%. In some embodiments, the specific wavelength is not greater than 400 nm, not greater than 350 nm, not greater than 300 nm, not greater than 250 nm, not greater than 200 nm, not greater than 150 nm, or not greater than 100 nm.

In some embodiments, the cover layer 40 includes a capping layer 410, an encapsulation layer 420, a filler layer 430 and a cover plate 440. In some embodiments, the capping layer 410 is arranged over the electrode 216, and is substantially conformal with a non-flat upper surface of the electrode 216. The capping layer 410 may include a dielectric material or an inorganic insulating material, for example, SiO₂. In some embodiments, the capping layer 410 may include a hole transport layer material to extract light lost inside the organic light-emitting element so as to improve light-emitting efficiency. The capping layer 410 may also be referred to as a light extraction layer.

In some embodiments, the encapsulation layer 420 is arranged over the capping layer 410, and is substantially conformal with a non-flat upper surface of the capping layer 410. The encapsulation layer 420 may include an oxide, for example, SiO₂. In some embodiments, the encapsulation layer 420 is substantially conformal with the non-flat upper surface of the capping layer 410, and includes a plurality of recesses corresponding to the organic light-emitting layers 260A, 260B and 260C. The encapsulation layer 420 may include a polymer organic material, for example, an epoxy-based material.

In some embodiments, the filler layer 430 is arranged over the encapsulation layer 420, and a lower surface of the filler layer 430 is substantially conformal with a non-flat upper surface of the encapsulation layer 420. The filler layer 430 may also be referred to as a flat layer. The filler layer 430 may include a polymer organic material, for example, an epoxy-based material.

In some embodiments, the cover plate 440 is arranged over a flat upper surface of the filler layer 430. The cover plate 440 may also be referred to as a protective layer. The cover plate 440 may include a transparent hard cover plate, for example, a glass plate. The cover plate 440 may be used to prevent components of the organic light-emitting element from coming into contact with external moisture and hence from malfunction and light emission failures of the components. In some embodiments, a surface 440a of the cover plate 440 is a light exiting surface.

In some embodiments, the inorganic barrier layer 268 is located between the electrodes 215, 225 and 235 and the organic light-emitting layers 260A, 260B and 260C. In some embodiments, a side surface of the inorganic barrier layer 268 is in contact with the protrusions 310. In some embodiments, the inorganic barrier layer 268 substantially completely covers interfaces between the electrodes 215, 225 and 235 and the organic light-emitting layers 260A, 260B and 260C. In some embodiments, the inorganic barrier layer 268 includes a transition metal oxide. In some embodiments, the inorganic barrier layer 268 includes molybdenum oxide (MoO₃). In some embodiments, a thickness of the inorganic barrier layer 268 is less than or equal to 100 Å. In some embodiments, a ratio of the thickness of the inorganic barrier layer 268 to the thicknesses of the electrodes 215, 225 and 235 is less than 0.1, 0.06 or 0.03. In some embodiments, the inorganic barrier layer 268 and the hole injection layers 261A and 261B may jointly form a hole injection layer of the organic light-emitting layers 260A, 260B and 260C.

In some embodiments, the inorganic barrier layer 270 is in contact with the capping layer 410. In some embodiments, the inorganic barrier layer 270 covers the electrode 216. In some embodiments, the capping layer 410 is located over the inorganic barrier layer 270, and is separated from the electrode 216 by the inorganic barrier layer 270. In some embodiments, the inorganic barrier layer 270 substantially completely covers an interface between the electrode 216 and the capping layer 410. In some embodiments, the inorganic barrier layer 270 includes a transition metal oxide. In some embodiments, the inorganic barrier layer 270 includes molybdenum oxide (MoO₃). In some embodiments, a thickness of the inorganic barrier layer 270 is less than or equal to 100 Å. In some embodiments, a ratio of the thickness of the inorganic barrier layer 270 to the thickness of the electrode 216 is less than 0.15, 0.1 or 0.05. In some embodiments, a ratio of the thickness of the inorganic barrier layer 270 to the thickness of the capping layer 410 is less than 0.5, 0.3 or 0.15.

Moreover, according to some embodiments of the present disclosure, the inorganic barrier layer 268 may be used to block metal atoms in the electrode 215 from diffusing into the organic light-emitting layers 260A, 260B and 260C (for example, the hole injection layer 261, the hole transport layer 262, the electron barrier layer 263 and the organic emissive layer 264) to avoid quenching, hence preventing degradation of light-emitting efficiency and further enhancing light-emitting luminance and improving a color rendering index (Ra) of an organic light-emitting element. Moreover, according to some embodiments of the present disclosure, the inorganic barrier layer 268 has an extremely small thickness relative to the electrodes 215, 225 and 235, and so the size in thickness of the organic light-emitting element is not significantly increased and an undesirable increase in a light-emitting path is likewise not resulted.

In addition, according to some embodiments of the present disclosure, the inorganic barrier layer 270 may be used to block metal atoms in the electrode 216 from diffusing into an organic layer (for example, the capping layer 410), hence preventing degradation of light-emitting efficiency and further enhancing light-emitting luminance and improving a color rendering index (Ra) of an organic light-emitting element. Moreover, according to some embodiments of the present disclosure, the inorganic barrier layer 270 has an extremely small thickness relative to the electrode 216 and the capping layer 410, and so the size in thickness of the organic light-emitting element is not significantly increased and an undesirable increase in a light-emitting path is likewise not resulted.

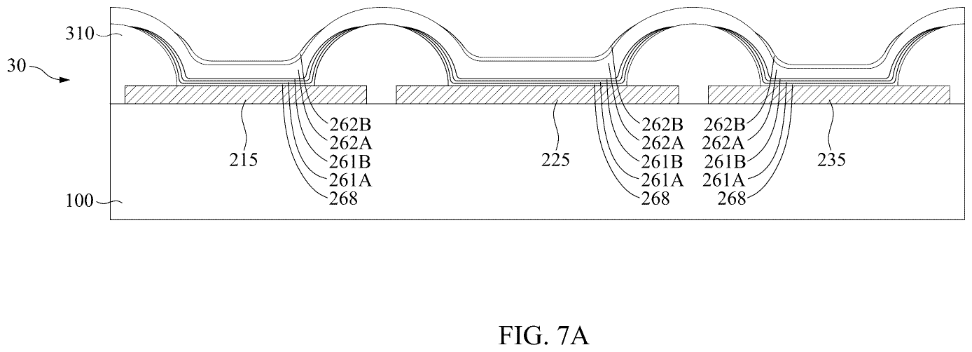

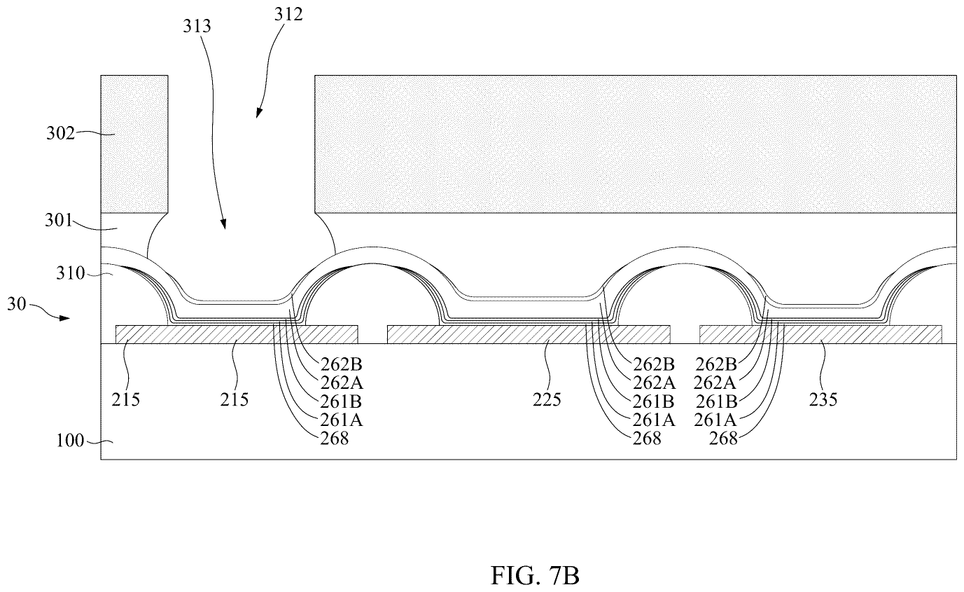

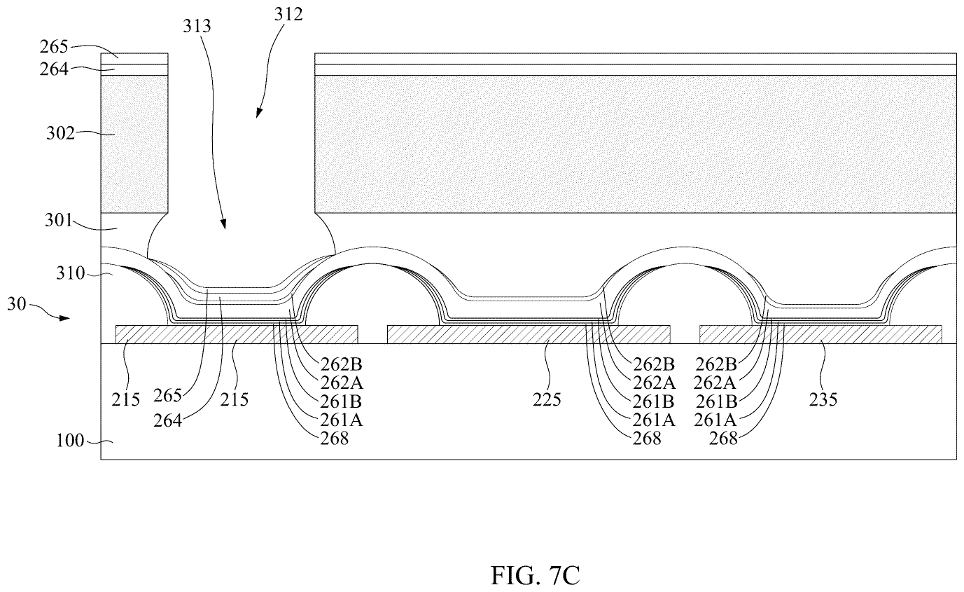

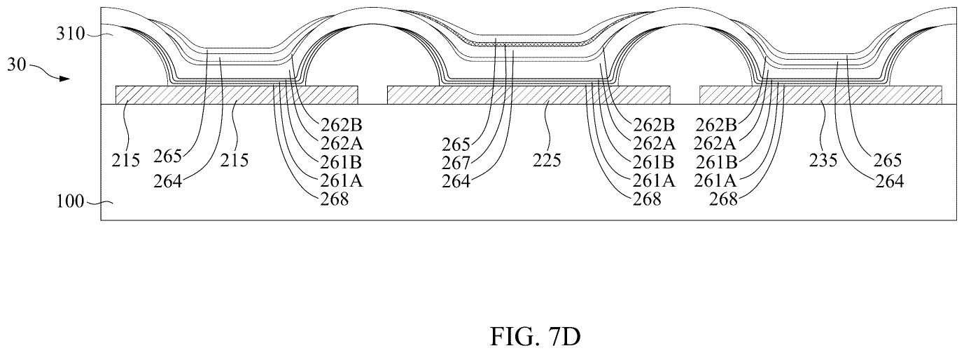

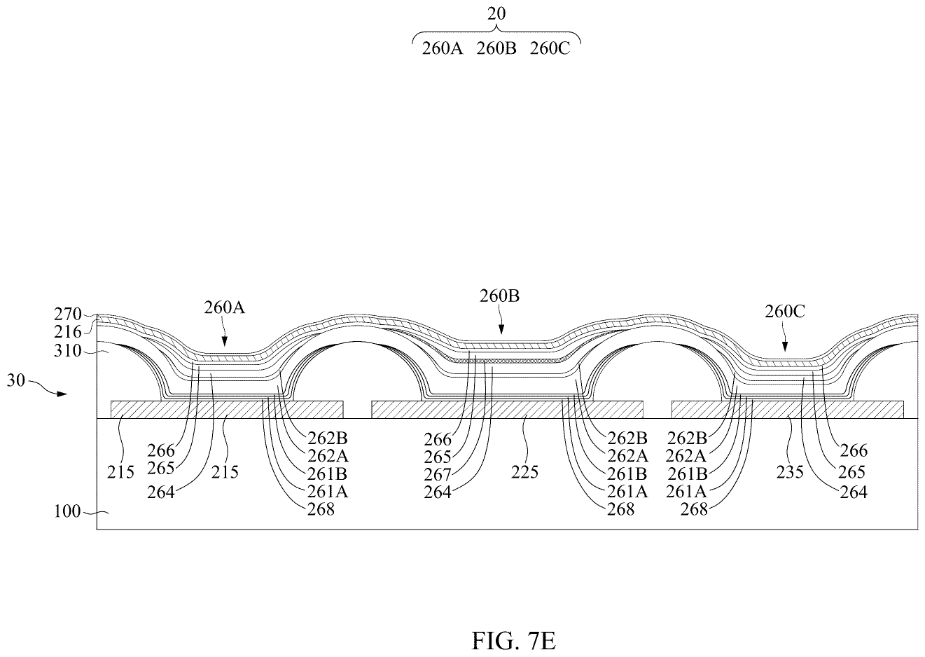

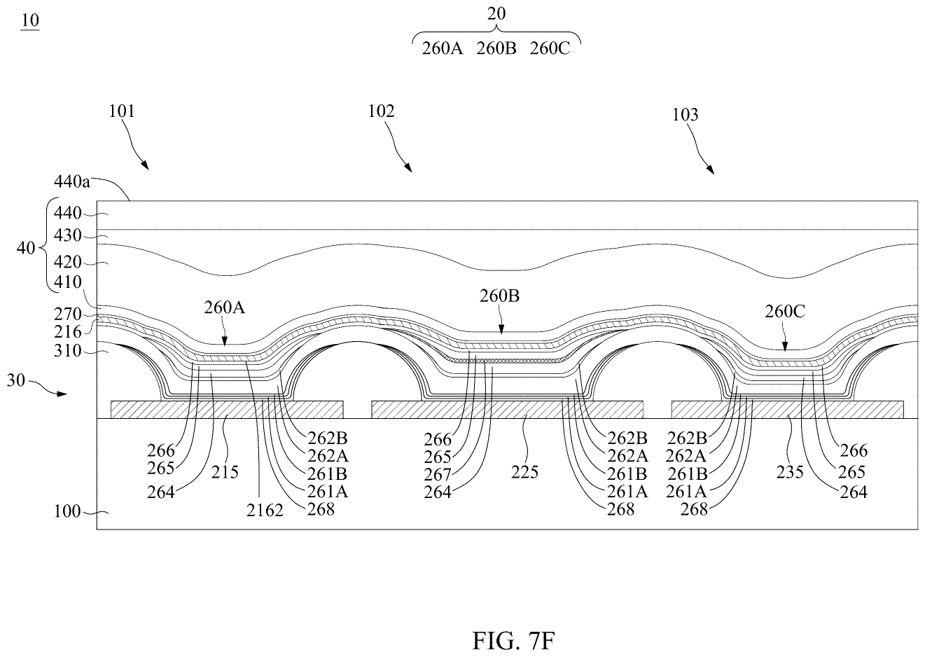

FIG. 7A to FIG. 7F depict a manufacturing method of the organic light-emitting element 10 in FIG. 6 according to some embodiments.

As shown in FIG. 7A, in some embodiments, a substrate 100 is provided, a plurality of electrodes 215, 225 and 235 are arranged over the substrate 100, and a plurality of protrusions 310 (or a spacer structure 30) are formed, wherein each of the protrusions 310 fills a gap between the adjacent electrodes 215, 225 and 235. In some embodiments, each protrusion 310 fills a gap between the adjacent electrodes 215, 225 and 235. In some embodiments, the electrodes 215, 225 and 235 are made of a transparent conductive material.

Next, in some embodiments, the inorganic barrier layer 268, the hole injection layer (HIL) 261A, the hole injection layer (HIL) 261B, the hole transport layer (HTL) 262A and the hole transport layer (HTL) 262B are arranged over surfaces of the protrusions 310 and the electrodes 215, 225 and 235. In some embodiments, the inorganic barrier layer 268, the hole injection layer 261A, the hole injection layer 261B, the hole transport layer 262A and the hole transport layer 262B are formed by means of evaporation. In some embodiments, the inorganic barrier layer 268, the hole injection layer 261A, the hole injection layer 261B, the hole transport layer 262A and the hole transport layer 262B may completely undergo the evaporation above the electrodes 215, 225 and 235. Due to smaller thicknesses of the inorganic barrier layer 268, the hole injection layer 261A, the hole injection layer 261B and the hole transport layer 262B, these layers above each of the electrodes 215, 225 and 235 are disconnected from one another via the protrusions 310. Due to a greater thickness of the hole transport layer 262A, the hole transport layer 262A is formed to continuously extend over the electrodes 215, 225 and 235 and the protrusions 310.

As shown in FIG. 7B, in some embodiments, a buffer layer 301 is arranged over the protrusions 310, and the buffer layer 301 also covers the inorganic barrier layer 268, the hole injection layer 261A, the hole injection layer 261B, the hole transport layer 262A, the hole transport layer 262B, and the electrodes 215, 225 and 235. The buffer layer 301 is for blocking moisture from passing through or entering the protrusions 310, the inorganic barrier layer 268, the hole injection layer 261A, the hole injection layer 261B, the hole transport layer 262A and the hole transport layer 262B. Next, in some embodiments, a photosensitive layer 302 is arranged over the buffer layer 301. In some embodiments, the buffer layer 301 and the photosensitive layer 302 are formed by means of coating. In some embodiments, the photosensitive layer 302 formed by means of coating contains changes in thickness. The thickness of the photosensitive layer 302 decreases gradually in a direction farther away from the center of the wafer W (as shown in FIG. 2A).

Next, in some embodiments, the photosensitive layer 302 is patterned by a lithography process, such that a portion of the buffer layer 301 is exposed through a groove 312. Next, in some embodiments, a portion of the buffer layer 301 is removed to form a groove 313, so as to expose the hole transport layer 262B. In some embodiments, the buffer layer 301 is removed by means of a wet etching process.

As shown in FIG. 7C, in some embodiments, the organic emissive layer (EML) 264 is arranged over the hole transport layer 262B by the grooves 312 and 313, and the electron transport layer (ETL) 265 is arranged over the organic emissive layer (EML) 264. In some embodiments, the organic emissive layer 264 and the electron transport layer 265 are formed by means of evaporation. In some embodiments, the thickness of the organic emissive layer 264 formed by means of evaporation on the hole transport layer 262B decreases as the patterned photosensitive layer 302 gets thicker.

As shown in FIG. 7D, in some embodiments, the buffer layer 301, the photosensitive layer 302 and portions of the organic emissive layer 264 and electron transport layer 265 above the photosensitive layer 302 are removed. In some embodiments, the buffer layer 301, the photosensitive layer 302, and the portions of the organic emissive layer 264 and the electron transport layer 265 are removed by means of a wet etching process. In some embodiments, the steps in FIG. 7B and FIG. 7C are repeated to form the organic emissive layer 264, the hole blocking layer (HBL) 267 and the electron transport layer 265 over the electrode 225, and the organic emissive layer 264 and the electron transport layer 265 are formed over the electrode 235. In some embodiments, the organic emissive layer 264, the hole blocking layer (HBL) 267 and the electron transport layer 265 are formed by means of evaporation.

As shown in FIG. 7E, in some embodiments, the electron injection layer (EIL) 266 is arranged over the protrusions 310 and the electron transport layer 265. Up to this point, organic light-emitting layers 260A, 260B and 260C (or a light-emitting layer 20) are formed. Next, in some embodiments, the electrode 216 is arranged over the organic light-emitting layers 260A, 260B and 260C and the spacer structure 30, and the inorganic barrier layer 270 is arranged over the electrode 216. Up to this point, the organic light-emitting units 101, 102 and 103 are formed.

As shown in FIG. 7F, in some embodiments, the capping layer 410 is arranged over the inorganic barrier layer 270. In some embodiments, the capping layer 410 is formed by means of evaporation. Next, in some embodiments, the encapsulation layer 420 is arranged over the capping layer 410. In some embodiments, the encapsulation layer 420 is formed by means of plasma-enhanced chemical vapor deposition (PECVD). Next, in some embodiments, the filler layer 430 is arranged over the encapsulation layer 420, and the cover plate 440 is arranged over the filler layer 430. Up to this point, the cover layer 40 including the capping layer 410, the encapsulation layer 420, the filler layer 430 and the cover plate 440 is formed. As shown in FIG. 7F, up to this point, the organic light-emitting element 10 shown in FIG. 6 is formed.

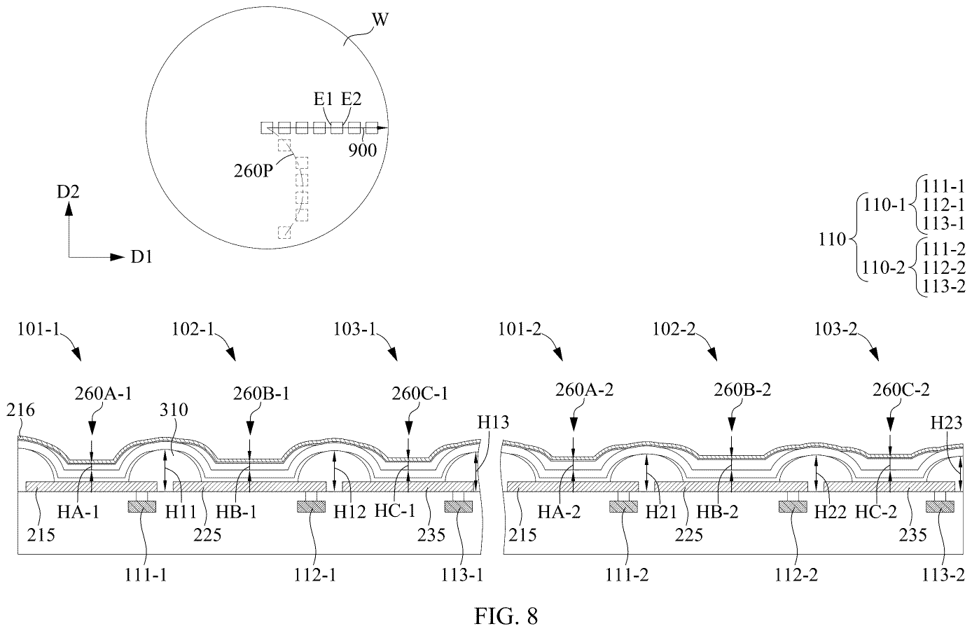

FIG. 8 is a schematic diagram of organic light-emitting layers of different organic light-emitting units of an organic light-emitting element according to some embodiments. FIG. 8 shows a partial cross-sectional diagram of an organic light-emitting element taken from one of the regions of the wafer W. To clearly present the description below, FIG. 8 depicts in brief the organic light-emitting units and omits some of the denotations. Refer to FIG. 6, FIG. 7A to FIG. 7F and associated description for details of the various material layers/components of the organic light-emitting units.

In some embodiments, at least two of the organic light-emitting units of the same color of light include organic light-emitting layers having different thicknesses. As shown in FIG. 8, the organic light-emitting unit in the selected region has a first side edge E1 and a second side edge E2. The second side edge E2 is opposite to the first side edge E1. In the organic light-emitting element, two of the organic light-emitting units include organic light-emitting layers of the same color of light but different thicknesses and are located in one horizontal direction, for example, arranged along the first direction D1 and respectively adjacent to the first side edge E1 and the second side edge E2.

Moreover, in some embodiments, as shown in FIG. 8, the organic light-emitting element includes a plurality of bottom electrodes (for example, the electrodes 215, 225 and 235 serving as anodes of the individual organic light-emitting units) arranged separately, the electrode 216 (or referred to as a top electrode), and the organic light-emitting layers located between the bottom electrodes 215, 225 and 235 and the top electrode 216.

As shown in FIG. 8, two pixels (each including three sub-pixels of different colors of light) are taken as an example in the description below. In some embodiments, in terms of manufacturing of the wafer W, organic light-emitting units 101-1, 102-1 and 103-1 are more adjacent to the first side edge E1 and closer to the center of the wafer than organic light-emitting units 101-2, 102-2 and 103-2. Thus, when manufacturing a patterned photoresist for defining the position of an organic light-emitting layer, the height of the photoresist is greater such that the organic light-emitting layer filled in later on has a smaller thickness.

In some embodiments, the organic light-emitting unit 101-1 and the organic light-emitting unit 101-2 include an organic light-emitting layer 260A-1 and an organic light-emitting layer 260A-2 emitting light of the same color (for example but not limited to, green) but having different thicknesses. In some embodiments, a thickness HA-1 of the organic light-emitting layer 260A-1 is less than a thickness HA-2 of the organic light-emitting layer 260A-2; that is, HA-1<HA-2.

In some embodiments, the organic light-emitting unit 102-1 and the organic light-emitting unit 102-2 include an organic light-emitting layer 260B-1 and an organic light-emitting layer 260B-2 emitting light of the same color (for example but not limited to, red) but having different thicknesses. In some embodiments, a thickness HB-1 of the organic light-emitting layer 260B-1 is less than a thickness HB-2 of the organic light-emitting layer 260B-2; that is, HB-1<HB-2.

In some embodiments, the organic light-emitting unit 103-1 and the organic light-emitting unit 103-2 include an organic light-emitting layer 260C-1 and an organic light-emitting layer 260C-2 emitting light of the same color (for example but not limited to, blue) but having different thicknesses. In some embodiments, a thickness HC-1 of the organic light-emitting layer 260C-1 is less than a thickness HC-2 of the organic light-emitting layer 260C-2; that is, HC-1<HC-2.

In some embodiments, the luminescence wavelengths (for example but not limited to, the wavelength of red light) of the organic light-emitting layers 260B-1 and 260B-2 are greater than the luminescence wavelengths (for example but not limited to, the wavelength of green light) of the organic light-emitting layers 260A-1 and 260A-2, and the luminescence wavelengths of the organic light-emitting layers 260A-1 and 260A-2 are greater than the luminescence wavelengths of the organic light-emitting layers 260C-1 and 260C-2 (for example but not limited to, the wavelength of blue light).

Moreover, in some embodiments, the protrusions 310 for defining and providing accommodation for a light-emitting pixel array may include an organic material, for example, a photosensitive material formed over the wafer W by means of spin coating and obtained by means of patterning. Thus, as described with reference to FIG. 1A, FIG. 1B and FIG. 2A above, the height of these protrusions 310, for example, the maximum vertical height, also changes along with positions on the wafer W during the manufacturing. In some embodiments, the organic light-emitting units 101-1, 102-1 and 103-1 are closer to the center than the organic light-emitting units 101-2, 102-2 and 103-2 when manufactured on the wafer W. Thus, in the course of manufacturing the protrusions 310, the maximum vertical height (or simply referred to as the height) of the protrusions 310 gradually decreases in a direction farther away from the center of the wafer W.

In some embodiments, the protrusions 310 corresponding to the organic light-emitting layers 260A-1, 260B-1, 260C-1, 260A-2, 260B-2 and 260C-2 are arranged from closer to the center of the wafer to closer to edges of the wafer, and thus heights H11, H12, H13, H21, H22 and H23 of the protrusions 310 are arranged from high to low. According to some embodiments, two organic light-emitting layers (a first light-emitting layer and a second light-emitting layer) of the same color of light have a first thickness and a second thickness greater than the first thickness, respectively, and the protrusions adjacent to the first light-emitting layer and the second light-emitting layer have a first height and a second height less than the first height, respectively.

In addition, in some embodiments, as described above, FIG. 8 further depicts optical shadow patterns of the organic light-emitting element, for example, the optical shadow arc 260P. The thicknesses of the organic light-emitting layers of each organic light-emitting unit below the optical shadow arc 260P are the same, and the thicknesses of the organic light-emitting layers below the optical shadow arc 260P are different from the thicknesses of the organic light-emitting layers outside the optical shadow arc 260P.

In addition, in some embodiments, the substrate 100 may include a silicon substrate and an insulating layer (not shown, for example but not limited to, a silicon dioxide layer) located above the silicon substrate. In some embodiments, the substrate 100 may include a transistor array, which is configured to correspond to light-emitting pixels in the light-emitting layer 20. The substrate 100 may include a plurality of capacitors (not shown). In some embodiments, transistors 110 are configured with a respective capacitors and a respective light-emitting pixels to form a respective circuits, so as to be electrically connected to and control a respective organic light-emitting units. For example, transistors 111-1, 112-1 and 113-1 (collectively referred to as a transistor 110-1) are electrically connected to the organic light-emitting unit 101-1, the organic light-emitting unit 102-1 and the organic light-emitting unit 103-1, respectively. Transistors 111-2, 112-2 and 113-2 (collectively referred to as a transistor 110-2) are electrically connected to the organic light-emitting unit 101-2, the organic light-emitting unit 102-2 and the organic light-emitting unit 103-2, respectively.

Although only two pixels are depicted in FIG. 8 as an example to describe the organic light-emitting element, the present disclosure is not limited to such example. In some embodiments, the organic light-emitting element may include multiple pixels, for example, three, four, five or more pixels, and thus the organic light-emitting element may include multiple organic light-emitting layers having different thicknesses but the same color of light. Moreover, according to an embodiment, Mura defects are present before luminance compensation is performed on an organic light-emitting element. However, after undergoing the luminance compensation above, for example, by controlling and applying an updated driving current value to the pixels by the transistor 110 coupled to the corresponding organic light-emitting unit, luminance balance of the organic light-emitting unit is achieved.

The features of some embodiments are described briefly above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made to the embodiments by a person skilled in the art without departing from the spirit and scope of the present disclosure.

What is claimed is:

1. An organic light-emitting element, comprising:
a substrate;
organic light-emitting units, located over the substrate, each of the organic light-emitting units comprising:
a first electrode, located over the substrate;
an organic light-emitting layer, located over the first electrode; and
a second electrode, located over the organic light-emitting layer, wherein one of the first electrode and the second electrode comprises a transparent conductive material;
wherein, at least two organic light-emitting units of the same color of light among the organic light-emitting units comprise organic light-emitting layers having different thicknesses.

2. The organic light-emitting element according to claim 1, wherein the first electrodes comprise electrode portions arranged separately, the organic light-emitting layers comprise first organic light-emitting layers, second organic light-emitting layers and third organic light-emitting layers configured to correspond to the electrode portions, respectively, a luminescence wavelength of the second organic light-emitting layers is greater than a luminescence wavelength of the first organic light-emitting layers, and at least two of second organic light-emitting units of the organic light-emitting units comprise the second organic light-emitting layers having different thicknesses.

3. The organic light-emitting element according to claim 2, wherein at least two of first organic light-emitting units of the organic light-emitting units comprise the first organic light-emitting layers having different thicknesses.

4. The organic light-emitting element according to claim 2, wherein the luminescence wavelength of the first organic light-emitting layers is greater than a luminescence wavelength of the third organic light-emitting layers, and at least two of third organic light-emitting units of the organic light-emitting units comprise the third organic light-emitting layers having different thicknesses.

5. The organic light-emitting element according to claim 1, further comprising pixel defined layers (PDL) to define pixel regions, wherein the first electrodes comprise electrode portions arranged separately in the pixel regions, the pixel defined layers comprise protrusions partially covering the electrode portions, and at least two of the protrusions have different maximum vertical heights.

6. The organic light-emitting element according to claim 5, wherein the protrusions comprise an organic material.

7. The organic light-emitting element according to claim 1, wherein protrusions in pixel regions of at least two of the organic light-emitting units defined with a same color of light have different maximum vertical heights.

8. The organic light-emitting element according to claim 1, wherein under a same driving current, at least two of the organic light-emitting units emitting a same color of light among the organic light-emitting units have different luminances.

9. The organic light-emitting element according to claim 1, wherein under a same grayscale value, a portion of the organic light-emitting units emitting the same color of light among the organic light-emitting units has a same luminance, and the portion of the organic light-emitting units is arranged in a sloped line or an arc.

10. The organic light-emitting element according to claim 9, wherein the portion of the organic light-emitting units having the same luminance comprises the organic light-emitting layers having a same thickness.

11. The organic light-emitting element according to claim 1, further comprising protrusions defining pixel regions, wherein at least two of the organic light-emitting layers of the same color of light are respectively a first light-emitting layer having a first thickness and a second light-emitting layer having a second thickness, and the protrusions comprise a first protrusion adjacent to the first light-emitting layer and a second protrusion adjacent to the second light-emitting layer, the first thickness is less than the second thickness, and a height of the first protrusion is greater than a height of the second protrusion.

12. The organic light-emitting element according to claim 1, having a first side edge and a second side edge, wherein the second side edge is opposite to the first side edge, and two of the organic light-emitting units comprising the organic light-emitting layers of the same color of light but different thicknesses are located in a horizontal direction and are respectively adjacent to the first side edge and the second side edge.

13. The organic light-emitting element according to claim 1, wherein at least three of the organic light-emitting units of a same color of light comprise organic light-emitting layers having different thicknesses.

14. The organic light-emitting element according to claim 1, comprising pixel regions arranged in matrices along a first direction and a second direction, wherein each of the pixel regions comprises at least three of the organic light-emitting units of different colors of light, and the organic light-emitting units of at least two of the pixel regions arranged along the first direction or the second direction comprise organic light-emitting layers having different thicknesses.

15. A method for correcting pixel luminance values of an organic light-emitting element, comprising:
providing an organic light-emitting element, wherein the organic light-emitting element comprises pixels and a pixel driving circuit, and the pixel driving circuit comprises driving transistors configured to provide driving currents to respective one of the pixels, wherein each of the pixels comprises an organic light-emitting unit over a substrate, and the organic light-emitting unit comprises an organic light-emitting layer between a first electrode and a second electrode, one of the first electrode and the second electrode comprises a transparent conductive material, wherein at least two organic light-emitting units of the same color of light among the organic light-emitting units comprise the organic light-emitting layers having different thicknesses;
applying the driving currents to the respective pixels by the driving transistors;
obtaining a grayscale image to be processed of the pixels;
calculating a balance luminance value of the grayscale image to be processed;
determining a luminance difference between a luminance value of each of the pixels and the balance luminance value; and
adjusting the driving currents to the respective pixels to compensate for the luminance difference.

16. The method for correcting pixel luminance values of an organic light-emitting element according to claim 15, wherein the pixels of a set color of the organic light-emitting element are lit by a set grayscale value to obtain the grayscale image to be processed, and the grayscale image to be processed has a non-uniform optical shadow pattern.

17. The method for correcting pixel luminance values of an organic light-emitting element according to claim 15, wherein the grayscale image to be processed of the pixels is obtained by an image capturing device, the image capturing device comprises a memory, a processor and a computer program stored in the memory and operable on the processor, and the processor executes the computer program to implement steps of the method for correcting pixel luminance values of the grayscale image to be processed.

18. The method for correcting pixel luminance values of an organic light-emitting element according to claim 15, wherein the grayscale image to be processed of the pixels is obtained by an image capturing device, the image capturing device is coupled to a computer readable storage medium, and luminance values of the grayscale image to be processed thus captured and obtained are calculated by a computer program stored in the computer readable storage medium to obtain updated driving current values for the respective pixels.

19. The method for correcting pixel luminance values of an organic light-emitting element according to claim 15, wherein a greater driving current is provided to pixels having lower luminances among the pixels, and a smaller driving current is provided to pixels having greater luminances among the pixels.
